(19) United States
(12) Patent Application Publication
(10) Pub. No.: US 2026/0006746 A1
(43) Pub. Date: Jan. 1, 2026

(54) INLINE LIQUID-DEGASSER WITH LOOPED FIBERS

(71) Applicant: AMD Design, LLC, Wilmington, DE (US)

(72) Inventors: Sruti CHIGULLAPALLI, Seattle, WA (US); Paul Harold ANDERSON, Leander, TX (US); Cameron CLEMENTS, Jersey City, NJ (US)

(73) Assignee: AMD Design, LLC, Wilmington, DE (US)

(21) Appl. No.: 18/758,505

(22) Filed: Jun. 28, 2024

(51) Int. Cl. H05K 7/20; B01D 63/02

(52) U.S. Cl. CPC H05K 7/20272; B01D 63/024; B01D 2313/131; B01D 2313/24

(57) ABSTRACT

The inline liquid-degasser (degasser) includes a gassed tube and a degassed tube with openings formed through the respective walls. The degasser also includes a baffle between the gassed tube and the degassed tube that is configured to seal an interior of the gassed tube from an interior of the degassed tube. The degasser further includes a degassing chamber surrounding an exterior of the gassed tube, where the openings of the gassed tube communicate therewith. The degasser also includes a vacuum chamber disposed adjacent to the degassing chamber and a vacuum port disposed through a wall of the vacuum chamber. The degasser further includes a plurality of hollow fibers with open ends. The hollow fibers are formed into loop portions and crown portions, where the loop portions surround the gassed tube in the degassing chamber and the crown portions extend to the vacuum chamber.

### FIELD

This disclosure is directed to an inline liquid-degasser, a degassing hose and a degassing heat-exchanger system for degassing a liquid of a server cooling system.

### BACKGROUND

Liquid cooling is quickly becoming the norm for server systems (e.g., artificial intelligence (AI) and high-performance computing (HPC) systems). Gases (e.g., nitrogen or oxygen) within the liquids used in such systems can be detrimental to the longevity and effectiveness of various components. For example, gases can cause premature corrosion of pipes, heat exchangers, pumps, valves, and other componentry.

One common source of gas introduction is when server racks are connected and disconnected from an infrastructure cooling system such as a sidecar heat exchanger (e.g., for testing, benchmarking, troubleshooting, quality assurance, etc.). Increasing the number of connections/disconnections introduces more gas. In certain scenarios, a single sidecar heat exchanger may have hundreds of server racks connected and disconnected thereto/from.

### SUMMARY

An inline liquid-degasser is described herein. The inline liquid-degasser includes a gassed tube with openings formed through a wall of the gassed tube. The inline liquid-degasser also includes a degassed tube with openings formed through a wall of the degassed tube. The inline liquid-degasser further includes a baffle between the gassed tube and the degassed tube. The baffle is configured to seal an interior of the gassed tube from an interior of the degassed tube. The inline liquid-degasser also includes a degassing chamber surrounding an exterior of the gassed tube. The openings of the gassed tube communicate with the degassing chamber. The inline liquid-degasser further includes a vacuum chamber disposed adjacent to the degassing chamber and a vacuum port disposed through a wall of the vacuum chamber. The inline liquid-degasser also includes a plurality of hollow fibers with open ends. The hollow fibers are formed into loop portions and crown portions. The loop portions are configured to surround the gassed tube in the degassing chamber. The crown portions are configured to extend through a wall separating the degassing chamber and the vacuum chamber such that the open ends communicate with the vacuum chamber.

A degassing hose is also described herein. The degassing hose includes the inline liquid-degasser, as described above. The degassing hose also includes a quick disconnect fitting attached to the vacuum port and a quick disconnect fitting attached to an end of the gassed tube. The hose further includes a hose attached to an end of the degassed tube and a quick disconnect fitting attached to an end of the hose.

A degassing heat-exchanger system is also described herein. The degassing heat-exchanger system includes a heat-exchanger including two liquid ports. The degassing heat-exchanger system also includes a first degassing hose, as described above, connected to one of the two liquid ports of the heat exchanger via an end of the gassed tube of the first degassing hose. The degassing heat-exchanger system also includes a second degassing hose, as described above, connected to another of the two liquid ports of the heat exchanger via an end of the hose of the second degassing hose.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of components of an inline liquid-degasser in accordance with this disclosure.

FIGS. 2A, 2B, and 2C illustrate an example of an inline liquid-degasser in accordance with this disclosure.

FIGS. 3A and 3B illustrate examples of a row of hollow fibers of an inline liquid-degasser in accordance with this disclosure.

FIG. 4 illustrates an example of a degassing hose using an inline liquid-degasser in accordance with this disclosure.

FIG. 5 illustrates an example of a degassing heat-exchanger system using multiple inline liquid-degassers in accordance with this disclosure.

FIG. 6 illustrates an example of a process flow for using a degassing heat-exchanger system using multiple degassing hoses in accordance with this disclosure.

### DETAILED DESCRIPTION

### Overview

Gas inclusion (dissolved and non-dissolved) within liquids of liquid-cooling systems can be problematic for associated systems and components. For example, many components may see decreased performance, increased corrosion, and/or decreased life when gases are present in cooling fluids. Mitigating gas inclusion is important, especially when new sources are constantly introduced. For example, in certain manufacturing and testing scenarios, a single sidecar heat exchanger may have hundreds of server racks connected and disconnected thereto/from, with each connection becoming a potential source of gas inclusion.

While degassing units have been developed, they are often plagued by one or more problems. For example, they may be too small or too big to work with the flow rates of a server system. Furthermore, the interstitial space of conventional systems (a surface area exposed to vacuum) may be small, thereby diminishing the degassing action.

Described herein is an inline liquid-degasser. The inline liquid-degasser includes a gassed tube and a degassed tube with openings formed through the respective walls. The inline liquid-degasser also includes a baffle between the gassed tube and the degassed tube that is configured to seal an interior of the gassed tube from an interior of the degassed tube. The inline liquid-degasser further includes a degassing chamber surrounding an exterior of the gassed tube, where the openings of the gassed tube communicate therewith. The inline liquid-degasser also includes a vacuum chamber disposed adjacent to the degassing chamber and a vacuum port disposed through a wall of the vacuum chamber. The inline liquid-degasser further includes a plurality of hollow fibers with open ends. The hollow fibers are formed into loop portions and crown portions, where the loop portions surround the gassed tube in the degassing chamber and the crown portions extend to the vacuum chamber.

The inline liquid-degasser may enable degassing of a cooling fluid without substantial pressure loss. Furthermore, the inline liquid-degasser may be configurable in length to accommodate various flow rates and amounts of gas inclusion.

As a system, the inline liquid-degasser may be disposed within one or more degassing hoses that may connect to an infrastructure cooling system (e.g., a sidecar heat exchanger). By connecting via the degassing hoses, many server racks may be sequentially connected to the cooling system without introducing large amounts of gases into the cooling system.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example Inline Liquid-Degasser

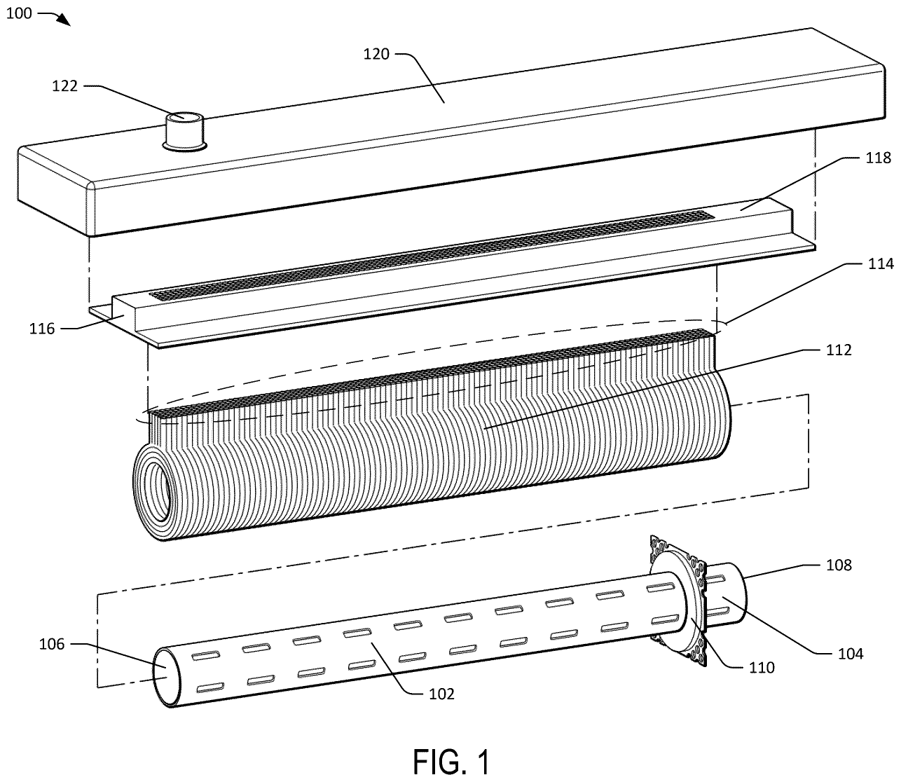

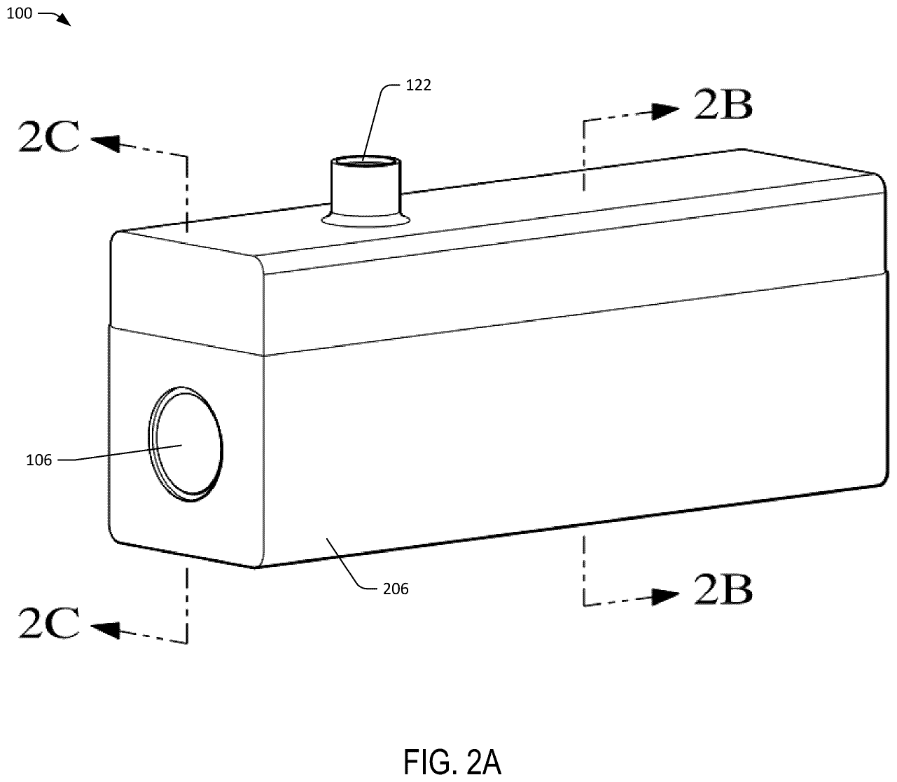

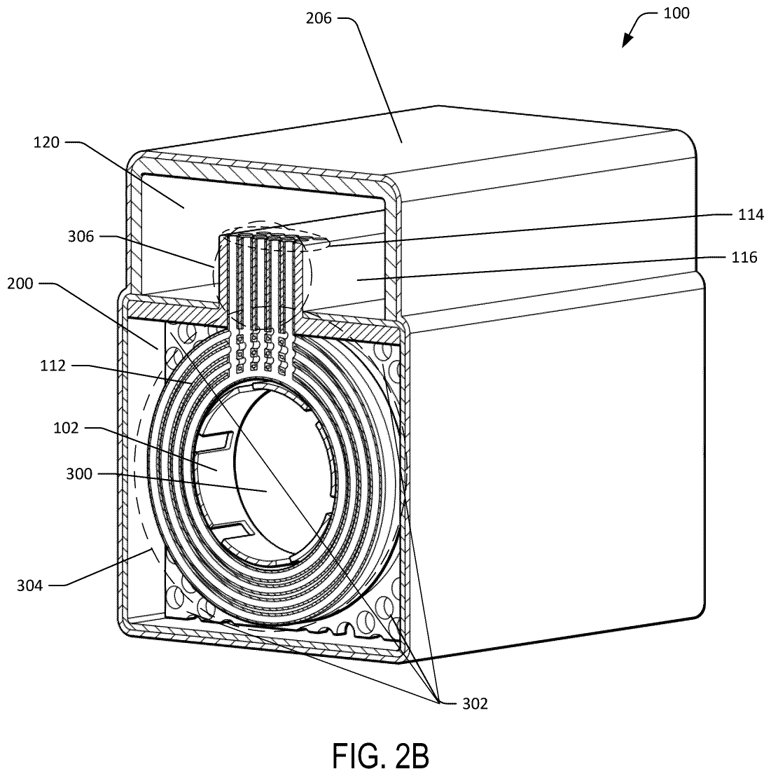

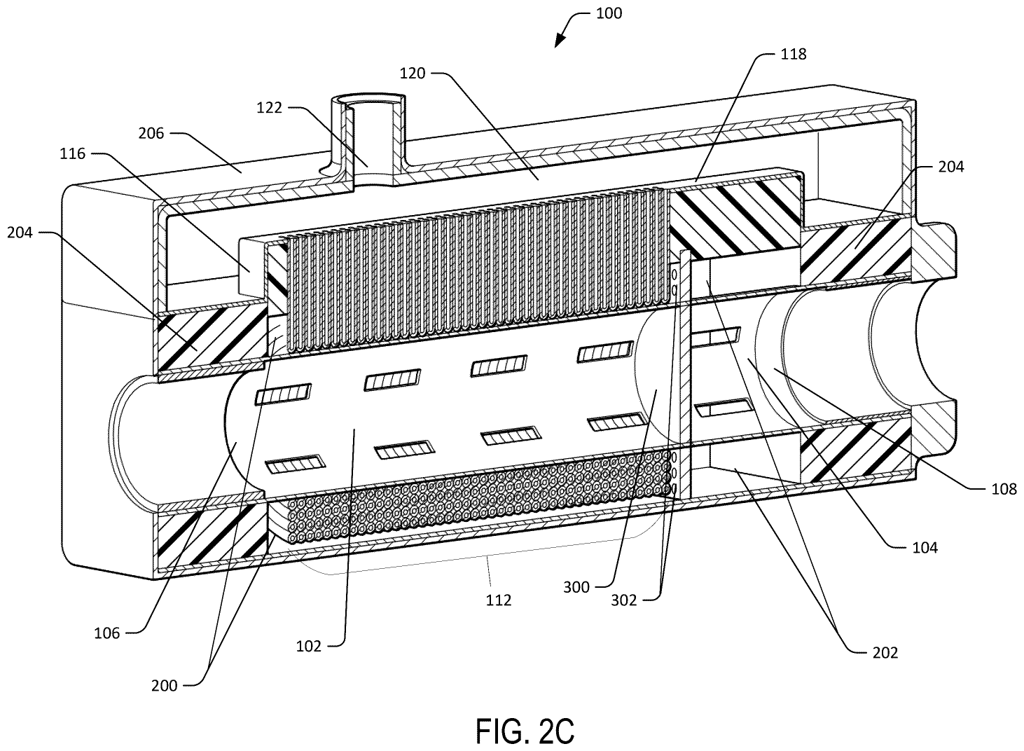

FIGS. 1-2C illustrate various components and views of an example of an inline liquid-degasser 100. The inline liquid-degasser 100 is generally a vacuum dual-wall membrane type device. FIG. 1 illustrates internal components of the inline liquid-degasser 100. FIG. 2A illustrates an example external structure of the inline liquid-degasser 100 including cross-section planes of FIGS. 2B and 2C. FIG. 2B illustrates a longitudinal cross-section of the inline liquid-degasser 100. FIG. 2C illustrates a lateral cross-section of the inline liquid-degasser 100. FIGS. 1-2C will be described in unison for conciseness.

The inline liquid-degasser 100 includes a gassed tube 102 and a degassed tube 104. The gassed tube 102 includes an inlet port 106, and the degassed tube 104 includes an outlet port 108. The inline liquid-degasser 100 is configured to have a cooling fluid enter the inlet port 106 and exit the outlet port 108 with less gas inclusion than at the inlet port 106.

The gassed tube 102 and the degassed tube 104 may be tubes or pipes with openings formed in the respective walls (e.g., perforated tubes or pipes). The openings may be holes, slots, apertures, slits, or equivalents thereof. In some implementations, the gassed tube 102 and the degassed tube 104 may be portions of the same tube. Regardless of whether they are multiple tubes or portions of a same tube, the gassed tube 102 and the degassed tube 104 may be colinear (e.g., disposed along a common axis) such that the inlet port 106 is colinear with the outlet port 108. In this way, the inline liquid-degasser 100 may be a true inline device.

Between the gassed tube 102 and the degassed tube 104 is a baffle 110. The baffle 110 is configured to not allow communication between interiors of the gassed tube 102 and the degassed tube 104. The baffle 110 effectively causes the cooling fluid to flow out of the gassed tube 102 through the openings in the wall of the gassed tube 102. The baffle 110 may also be configured to separate a degassing chamber 200 on an outside of the gassed tube 102 from a degassed chamber 202 on an outside of the degassed tube 104 and allow communication of the cooling fluid therebetween (e.g., via a perforated portion or piece).

To do so, the baffle 110 may be one or more pieces. For example, the baffle 110 may be multiple pieces, and the gassed tube 102 and the degassed tube 104 may be a single tube with a solid portion 300 of the baffle 110 within the pipe and a perforated portion 302 of the baffle 110 (e.g., a separate component than the solid portion 300) outside the pipe. The perforated portion 302 may have any number and/or configuration of openings formed therethrough (e.g., holes, slots, apertures, slits, or equivalents thereof). Conversely, the baffle 110 may be a single piece (with the solid portion 300 and the perforated portion 302), and the gassed tube 102 and the degassed tube 104 may be separate pipes that are both attached to the solid portion 300 of the baffle 110 (e.g., each sealed to one side of the solid portion 300). In some implementations, the baffle 110 may not have a perforated portion 302. In such implementations, the baffle 110 may consist of the solid portion 300 either within a single tube (if the gassed tube 102 and the degassed tube 104 are formed of a single tube) or between the gassed tube 102 and the degassed tube 104 (if the gassed tube 102 and the degassed tube 104 are separate components). The sizes, shapes, and configuration of the solid portion 300 and the perforated portion 302 of the baffle 110 may vary without departing from the scope of this disclosure.

Surrounding the gassed tube 102 and within the degassing chamber 200 is a plurality of hollow fibers 112. The hollow fibers 112 may be arranged in rows of one or more hollow fibers 112 (with each adjacent row being along a longitudinal axis of the gassed tube 102). The degassing chamber 200 may have a square cross-section with sides just long enough to accommodate a width of the hollow fibers 112. Although not required, the degassing chamber 200 and/or the hollow fibers 112 may extend a length of the gassed tube 102. The perforated portion 302 of the baffle 110 (if implemented) may be configured to keep the hollow fibers 112 from translating into the degassed chamber 202.

The hollow fibers 112 may be formed of a semi-permeable membrane that is configured to allow gasses to pass therethrough but not liquids. Each of the hollow fibers 112 forms a tube with two open ends. Thus, the group of hollow fibers 112 forms a group of open ends 114.

Loop portions 304 of the hollow fibers 112 surround the gassed tube 102 while crown portions 306 of the hollow fibers 112 extend through a separation wall 116 between the degassing chamber 200 (where the loop portions 304 are disposed) and a vacuum chamber 120. The loop portions 304 of the hollow fibers 112 of a row may have respective radii (e.g., each hollow fiber of the row may have a loop portion 304 with a different radius). The separation wall 116 may form a wall (e.g., bottom) of the vacuum chamber 120. The open ends 114 communicate with a top surface 118 of the separation wall 116 (and, thus, with the vacuum chamber 120). The inline liquid-degasser 100 is configured such that a vacuum within the vacuum chamber 120 is communicated with an interior of the hollow fibers 112 but not to the degassing chamber 200 (or any other portion of the inline liquid-degasser 100).

The hollow fibers 112 may be attached to the separation wall 116 such that the open ends 114 are inserted through respective holes through the separation wall 116. In some implementations, the separation wall 116 may be formed around the crown portions 306 of the hollow fibers 112 (e.g., via a potting operation) such that the open ends 114 can communicate with the vacuum chamber 120.

The vacuum chamber 120 has a vacuum port 122 that is configured to provide vacuum to the vacuum chamber 120. The open ends 114 of the hollow fibers 112 communicate with the vacuum chamber 120 via the top surface 118. When a vacuum is applied to the vacuum chamber 120 (e.g., via the vacuum port 122), the vacuum is transferred to the interiors of the hollow fibers 112. As the cooling liquid passes over the loop portions 304 (e.g., within the degassing chamber 200), gasses may be pulled from the fluid into the interiors of the hollow fibers 112, into the vacuum chamber 120, and out through the vacuum port 122.

The vacuum chamber 120 is adjacent or “above” the degassing chamber 200. The extents of the vacuum chamber 120 may vary without departing from the scope of this disclosure.

To support the inlet port 106 and the outlet port 108 blocks 204 may be utilized. The blocks 204 may have holes therethrough that the gassed tube 102 and the degassed tube 104 may be disposed through. The blocks 204 may also support connections to the gassed tube 102 and the degassed tube 104 (e.g., for use in a hose assembly as described below).

Surrounding the components described above is a housing 206. The housing 206 is configured to maintain the position of components relative to each other and to protect the inline liquid-degasser 100 from damage. The housing 206 may be one or more pieces/components.

The inline liquid-degasser 100 may form a rectangular shape. For example, the inline liquid-degasser 100 may be taller than it is wide due to the presence of the vacuum chamber 120 above the degassing chamber 200. Although the length may vary depending upon a number of rows of hollow fibers 112 needed for a certain degassing application, the length is generally longer than the width and height of the inline liquid-degasser 100.

Degassing occurs via a flow of the cooling fluid through the inline liquid-degasser 100. The cooling fluid enters an interior of the gassed tube 102 via the inlet port 106. The cooling fluid flows through the openings of the gassed tube 102 into the degassing chamber 200 where the loop portions 304 of the hollow fibers 112 are disposed. The cooling fluid flows over/around the loop portions 304 of the hollow fibers 112 while a vacuum is pulled through an interior of the hollow fibers 112 (e.g., via the vacuum chamber 120 and the open ends 114). The cooling fluid flows through the degassing chamber 200 towards the baffle 110. The cooling fluid then flows into the degassed chamber 202 that surrounds the degassed tube 104. If the baffle 110 extends outside perimeters of the gassed tube 102 and the degassed tube 104, the cooling fluid may flow into the degassed chamber 202 from the degassing chamber 200 through the perforated portion 302. If not, the transition from the degassing chamber 200 to the degassed chamber 202 may simply be an end of the hollow fibers 112. The cooling fluid then flows through the openings of the degassed tube 104 into an interior of the degassed tube 102 and out of the outlet port 108.

It should be noted that the direction of flow may be reversed without departing from the scope of this disclosure. For example, the cooling fluid may enter the degassed tube 104 via the outlet port 108, flow over the hollow fibers 112 in the degassing chamber 200 away from the baffle 110, flow into the interior of the gassed tube 102, and exit the gassed tube 102 via the inlet port 106. The structure and operation of such an implementation is similar with the only change being a fluid direction change.

### Example Row of Hollow Fibers

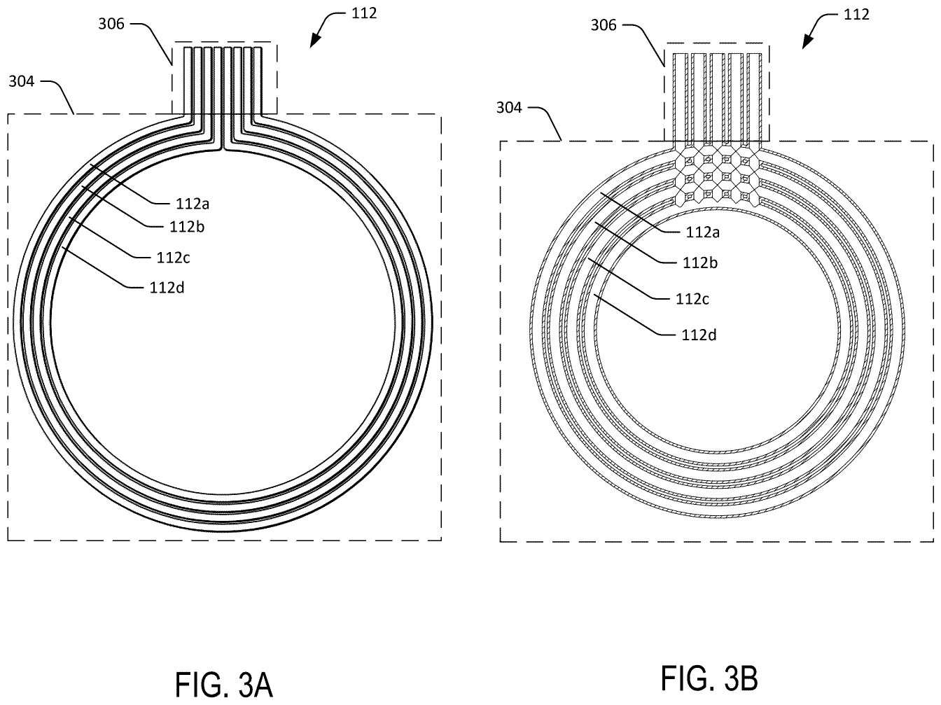

FIGS. 3A and 3B illustrate examples of a row of the hollow fibers 112 (e.g., a slice along the longitudinal axis). FIG. 3A illustrates an example implementation where the hollow fibers 112 of the row are not interconnected. FIG. 3B illustrates an example implementation where the hollow fibers 112 of the row are interconnected. FIGS. 3A and 3B also illustrate the loop portions 304 and the crown portions 306.

In FIG. 3A, the row comprises a plurality of hollow fibers 112 (e.g., hollow fibers 112a, 112b, and 112c). The hollow fibers 112a-c are not interconnected in the illustrated implementation. That is, each hollow fiber 112 acts independently of the others.

In FIG. 3B, the row also comprises a plurality of hollow fibers 112 (e.g., hollow fibers 112a, 112b, and 112c). However, the hollow fibers 112a-c are interconnected in the illustrated implementation. That is, a vacuum within one of the hollow fibers 112 may be transferred to one or more others of the hollow fibers 112.

Regardless of whether the hollow fibers 112 are interconnected, the crown portions 306 may be similar. As such, the connection of the crown portions 306 (e.g., the open ends 114) to the vacuum chamber 120 via the separation wall 116 may not be affected by a configuration of the hollow fibers 112. For example, the open ends of the hollow fiber 112a are further apart than the open ends of the hollow fiber 112b. Similarly, the open ends of the hollow fiber 112b are further apart than the open ends of the hollow fiber 112c. Thus, the open ends of the hollow fibers 112 of a row may be spaced apart at respective distances.

### Example Degassing Hose

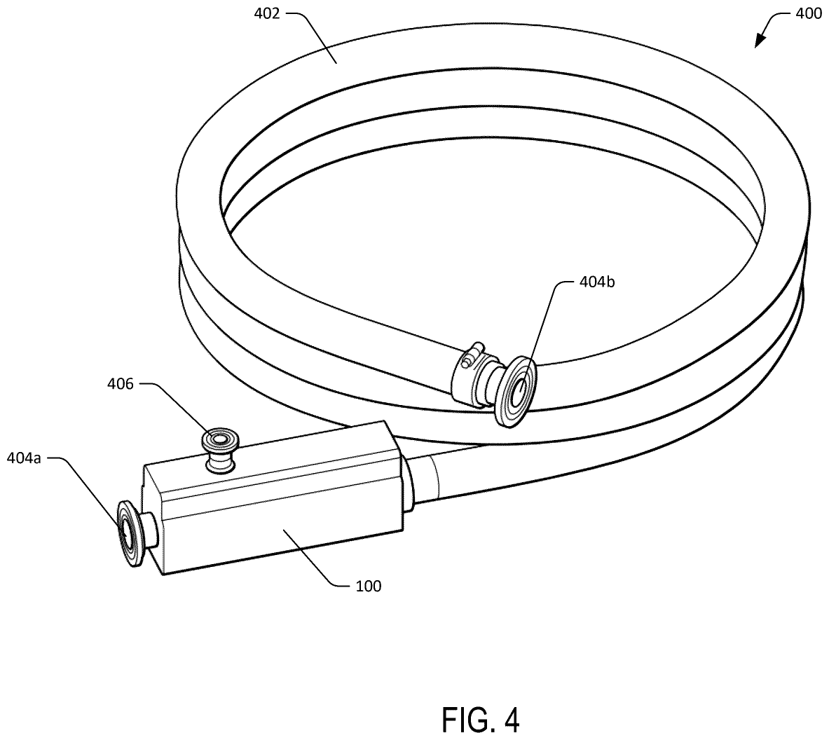

FIG. 4 illustrates an example of a degassing hose 400 incorporating the inline liquid-degasser 100. Along with the inline liquid-degasser 100, the degassing hose 400 includes a hose 402, liquid quick-disconnect fittings 404 (e.g., 404a and 404b), and a vacuum quick-disconnect 406. Although shown as sanitary fittings, the quick-disconnects may be type of connector/connection. For example, the quick-disconnects may be push-to-connect fittings, ball and sleeve couplings, hydraulic fittings, or any other pneumatic or fluid connector. Furthermore, the quick-disconnects may be different sizes and/or types of fittings (e.g., the three quick-disconnects may all be different). The configuration of the inline liquid-degasser 100 has been discussed above and, thus, will not be repeated here.

The liquid quick-disconnect 404a may be coupled with the inlet port 106. For example, the inline liquid-degasser 100 may contain a threaded portion or other connection means (e.g. in one of the blocks 204) for attaching the liquid quick-disconnect 404a thereto. In some implementations, the liquid quick-disconnect 404a may be directly attached/adhered to the inline liquid-degasser 100.

The hose 402 may be coupled with the outlet port 108. For example, the inline liquid-degasser 100 may contain a threaded portion or other connection means (e.g., in one of the blocks 204) for attaching a hose barb or other hose/pipe connection thereto. The hose 402 may then be connected to the hose barb or other hose/pipe connection. In some implementations, the hose 402 may be directly attached/adhered to the inline liquid-degasser 100.

The liquid quick-disconnect 404b may be coupled to an end of the hose 402 opposite the inline liquid-degasser 100. The liquid quick-disconnect 404b may be similar to or different from the liquid quick-disconnect 404a (e.g., a different size or type).

The vacuum quick-disconnect 406 may be coupled with the vacuum port 122. For example, the inline liquid-degasser 100 may contain a threaded portion or other connection means for attaching the liquid quick-disconnect 404a thereto. In some implementations, the liquid quick-disconnect 404a may be directly attached/adhered to the inline liquid-degasser 100.

Accordingly, as illustrated, the degassing hose 400 is configured such that the liquid quick-disconnect 404a is an inlet and the liquid quick-disconnect 404b is an outlet. The configuration of the degassing hose 400 and flow direction therethrough may change without departing form the scope of this disclosure, however. For example, the degassing hose 400 may be configured such that the liquid quick-disconnect 404b is an inlet and the liquid quick-disconnect 404a is an outlet. Furthermore, the hose 402 may be coupled with the inlet port 106 and the quick-disconnect 404a coupled with the outlet port 108.

### Example Heat Exchanger System

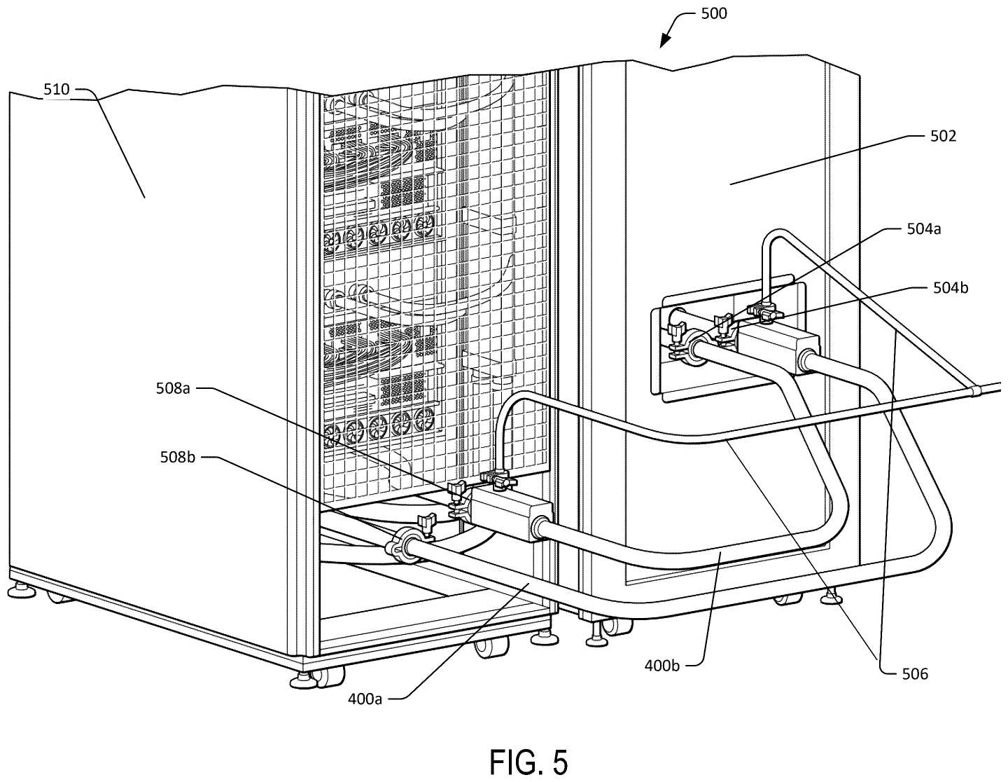

FIG. 5 illustrates an example of a heat exchanger system 500 using degassing hoses 400. The heat exchanger system 500 includes a heat exchanger 502 (e.g., a sidecar heat exchanger) with two liquid ports 504 (e.g., liquid port 504a and liquid port 504b). One of the liquid ports 504 may be an inlet port, and another of the liquid ports 504 may be an outlet port. The two liquid ports 504 may comprise quick-disconnect fittings configured to interface with the liquid quick-disconnect fittings 404 of the degassing hose 400.

Connected to the two liquid ports 504 are degassing hoses 400 (e.g., degassing hose 400a and degassing hose 400b). The degassing hoses 400 are connected opposite each other. That is, an inlet of one of the degassing hoses 400 is coupled with one of the liquid ports 504, and an outlet of the other degassing hose 400 is coupled with the other of the liquid ports 504. As discussed above, the orientation and flow direction of the degassing hoses 400 may vary without departing from the scope of this disclosure. Furthermore, in some implementations, only a single degassing hose 400 may be utilized (e.g., the other hose may be a standard hose).

A vacuum line 506 is connected to the vacuum quick-disconnects 406 of the degassing hoses 400. Thus, when the degassing hoses 400 are connected to liquid ports 508 (e.g., liquid port 508a and liquid port 508b) of a server rack 510, vacuum is pulled in the vacuum line 506, and cooling fluid is flowing between the heat exchanger 502 and the server rack 510, the cooling fluid may be degassed.

### Example Process

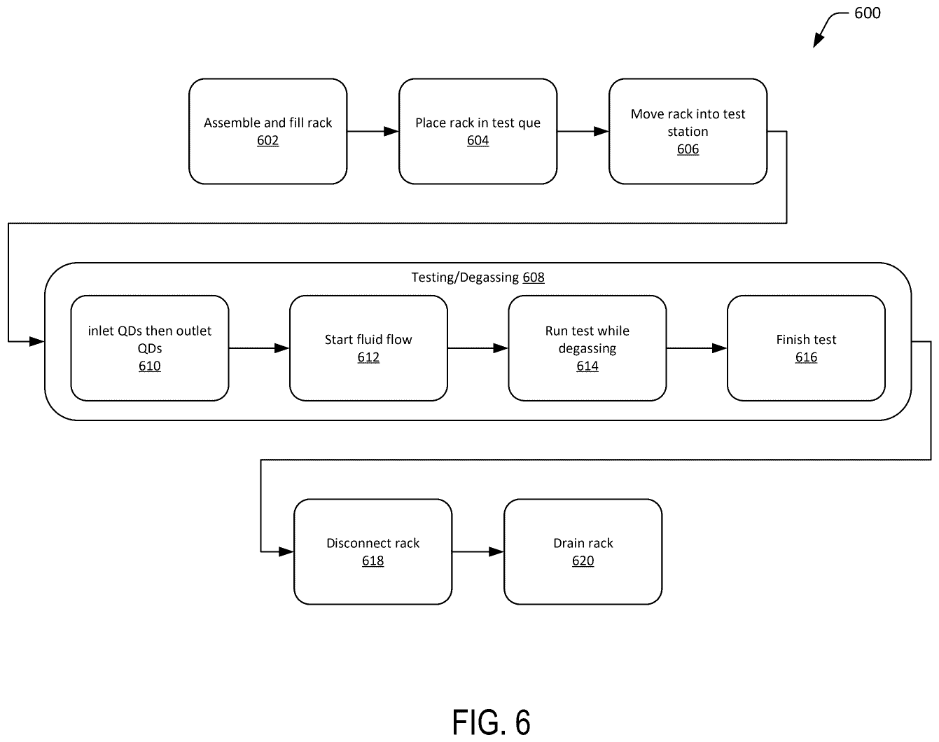

FIG. 6 illustrates an example of a process flow 600 that uses the heat exchanger system 500. The steps of the process flow 600 may be combined, separated, or rearranged without departing from the scope of this disclosure.

At 602, a server rack may be assembled and filled with a cooling fluid. For example, the server rack 510 may be assembled (e.g., with servers and associated components) and filled with a cooling fluid (e.g., glycol).

At 604, the server rack may be placed within a test que. For example, the server rack 510 may be placed in a test que for a test station that utilizes the heat exchanger system 500.

At 606, the server rack may be moved into a test station. For example, the server rack 510 may be placed within the test station that utilizes the heat exchanger system 500. In many cases, doing so may involve placing the server rack 510 proximate and/or adjacent to the heat exchanger system 500.

From there the server rack may undergo testing and degassing operations 608 (e.g., operations 610-616). For example, the server rack 510 may begin whatever testing is being done on it while degassing the cooling fluid within the server and the heat exchanger system 500.

At 610, assuming vacuum is already being applied to degassing hoses of the test station, inlet quick-disconnects may be connected and then outlet quick disconnects may be connected. For example, assuming vacuum is already being applied to the degassing hoses 400 of the heat exchanger system 500, the inlets of the degassing hoses 400 may be connected first, followed by the outlets of the degassing hoses 400. In some implementations, the inlets of the degassing hoses 400 are those coupled to the gassed tubes 102, and the outlets of the degassing hoses 400 are those coupled to the degassed tubes 104. In many cases, the degassing hoses 400 will already be connected to the heat exchanger 502. In such cases, only one inlet connection and one outlet connection may need to be made (e.g., those to liquid ports 508a and 508b). In some implementations, step 610 may involve causing the vacuum to be applied to the degassing hoses 400.

At 612, fluid flow may be started. It should be noted that, in some implementations, fluid flow may be started when the server rack 510 is connected to the heat exchanger system 500. If not, a pump may be started or a valve opened to enable the cooling fluid to flow between the heat exchanger system 500 and the server rack 510.

At 614, a test is run on the server rack while the cooling fluid is degassed. It should be noted that the cooling fluid may start being degassed when the fluid flow is started.

At 616, the test is completed. Completing the test may involve causing the fluid flow and/or the vacuum to stop.

At 618, the server rack is disconnected from the test station. For example, the degassing hoses 400a and 400b may be disconnected from the liquid ports 508.

At 620, the server rack may be drained and moved to a next step. For example, the server rack 510 may be drained of its cooling fluid and prepped for shipping.

### EXAMPLES

Example 1: An inline liquid-degasser comprising: a gassed tube with openings formed through a wall of the gassed tube; a degassed tube with openings formed through a wall of the degassed tube; a baffle between the gassed tube and the degassed tube, the baffle configured to seal an interior of the gassed tube from an interior of the degassed tube; a degassing chamber surrounding an exterior of the gassed tube, the openings of the gassed tube communicating with the degassing chamber; a vacuum chamber disposed adjacent to the degassing chamber; a vacuum port disposed through a wall of the vacuum chamber; and a plurality of hollow fibers with open ends, the hollow fibers formed into loop portions and crown portions, the loop portions configured to surround the gassed tube in the degassing chamber, the crown portions configured to extend through a wall separating the degassing chamber and the vacuum chamber such that the open ends communicate with the vacuum chamber.

Example 2: The inline liquid-degasser of example 1, wherein the gassed tube and the degassed tube are colinear.

Example 3: The inline liquid-degasser of example 1 or 2, including a degassed chamber surrounding an exterior of the degassed tube and adjacent to the degassing chamber, the openings of the degassed tube communicating with the degassing chamber.

Example 4: The inline liquid-degasser of example 3, wherein the baffle separates the degassing chamber and the degassed chamber.

Example 5: The inline liquid-degasser of example 4, wherein: the baffle has a solid portion without openings therethrough and a perforated portion with openings therethrough; the gassed tube is sealed to one side of the solid portion and the degassed tube is sealed to another side of the solid portion; and the perforated portion separates the degassing chamber and the degassed chamber.

Example 6: The inline liquid-degasser of example 3, wherein: the gassed tube and the degassed tube are portions of a single tube; and the baffle is sealed to a wall of the single tube.

Example 7: The inline liquid-degasser of example 6, including a perforated portion formed as a separate component than the baffle and disposed between the degassing chamber and the degassed chamber.

Example 8: The inline liquid-degasser of any previous example, wherein the hollow fibers are arranged in rows of one or more hollow fibers.

Example 9: The inline liquid-degasser of example 8, wherein: each of the rows contains a plurality of hollow fibers; and the loop portions of the plurality of hollow fibers have respective radii.

Example 10: The inline liquid-degasser of example 9, wherein the plurality of hollow fibers are interconnected.

Example 11: The inline liquid-degasser of example 9 or 10, wherein the open ends of the hollow fibers of a row are at respective distances from each other.

Example 12: The inline liquid-degasser of any previous example, wherein the degassing chamber has a square cross-section.

Example 13: The inline liquid-degasser of any previous example, wherein the inline liquid-degasser has a rectangular shape.

Example 14: The inline liquid-degasser of any previous example, containing a quick disconnect fitting coupled with an inlet port of the gassed tube.

Example 15: The inline liquid-degasser of any previous example, containing a hose barb coupled with an outlet port of the degassed tube.

Example 16: A degassing hose comprising: an inline liquid-degasser including: a gassed tube with openings formed through a wall of the gassed tube; a degassed tube with openings formed through a wall of the degassed tube; a baffle between the gassed tube and the degassed tube, the baffle configured to seal an interior of the gassed tube from an interior of the degassed tube; a degassing chamber surrounding an exterior of the gassed tube, the openings of the gassed tube communicating with the degassing chamber; a vacuum chamber disposed adjacent to the degassing chamber; a vacuum port disposed through a wall of the vacuum chamber; and a plurality of hollow fibers with open ends, the hollow fibers formed into loop portions and crown portions, the loop portions configured to surround the gassed tube in the degassing chamber, the crown portions configured to extend through a wall separating the degassing chamber and the vacuum chamber such that the open ends communicate with the vacuum chamber; a quick disconnect fitting attached to the vacuum port; a quick disconnect fitting attached to an end of the gassed tube; a hose attached to an end of the degassed tube; and a quick disconnect fitting attached to an end of the hose.

Example 17: The degassing hose of example 16, wherein the gassed tube and the degassed tube are colinear.

Example 18: The degassing hose of example 16 or 17, including a degassed chamber surrounding an exterior of the degassed tube and adjacent to the degassing chamber, the openings of the degassed tube communicating with the degassing chamber.

Example 19: The degassing hose of example 16, 17, or 18, wherein: the baffle has a solid portion without openings therethrough and a perforated portion with openings therethrough; the gassed tube is sealed to one side of the solid portion and the degassed tube is sealed to another side of the solid portion; and the perforated portion separates the degassing chamber and the degassed chamber.

Example 20: A degassing heat-exchanger system comprising: a heat exchanger including two liquid ports; a first degassing hose coupled with one of the two liquid ports of the heat exchanger, the first degassing hose comprising: an inline liquid-degasser including: a gassed tube with openings formed through a wall of the gassed tube, an end of the gassed tube coupled with the one of the two liquid ports; a degassed tube with openings formed through a wall of the degassed tube; a baffle between the gassed tube and the degassed tube, the baffle configured to seal an interior of the gassed tube from an interior of the degassed tube; a degassing chamber surrounding an exterior of the gassed tube, the openings of the gassed tube communicating with the degassing chamber; a vacuum chamber disposed adjacent to the degassing chamber; a vacuum port disposed through a wall of the vacuum chamber; and a plurality of hollow fibers with open ends, the hollow fibers formed into loop portions and crown portions, the loop portions configured to surround the gassed tube in the degassing chamber, the crown portions configured to extend through a wall separating the degassing chamber and the vacuum chamber such that the open ends communicate with the vacuum chamber; a hose coupled with an end of the degassed tube; and a quick disconnect fitting attached to an end of the hose and configured to mate with a quick disconnect fitting on a server rack; and a second degassing hose attached to another of the two liquid ports, the second degassing hose comprising: an inline liquid-degasser including: a gassed tube with openings formed through a wall of the gassed tube; a degassed tube with openings formed through a wall of the degassed tube; a baffle between the gassed tube and the degassed tube, the baffle configured to seal an interior of the gassed tube from an interior of the degassed tube; a degassing chamber surrounding an exterior of the gassed tube, the openings of the gassed tube communicating with the degassing chamber; a vacuum chamber disposed adjacent to the degassing chamber; a vacuum port disposed through a wall of the vacuum chamber; and a plurality of hollow fibers with open ends, the hollow fibers formed into loop portions and crown portions, the loop portions configured to surround the gassed tube in the degassing chamber, the crown portions configured to extend through a wall separating the degassing chamber and the vacuum chamber such that the open ends communicate with the vacuum chamber; a quick disconnect fitting coupled with an end of the gassed tube and configured to mate with another quick disconnect fitting on the server rack; and a hose coupling an end of the degassed tube with another of the two liquid ports of the heat exchanger; and a vacuum line coupled to the vacuum port of the first degassing hose and the vacuum port of the second degassing hose.

### CONCLUSION

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description, but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. An inline liquid-degasser comprising:
a gassed tube with openings formed through a wall of the gassed tube;
a degassed tube with openings formed through a wall of the degassed tube;
a baffle between the gassed tube and the degassed tube, the baffle configured to seal an interior of the gassed tube from an interior of the degassed tube;
a degassing chamber surrounding an exterior of the gassed tube, the openings of the gassed tube communicating with the degassing chamber;
a vacuum chamber disposed adjacent to the degassing chamber;
a vacuum port disposed through a wall of the vacuum chamber; and
a plurality of hollow fibers with open ends, the hollow fibers formed into loop portions and crown portions, the loop portions configured to surround the gassed tube in the degassing chamber, the crown portions configured to extend through a wall separating the degassing chamber and the vacuum chamber such that the open ends communicate with the vacuum chamber.

2. The inline liquid-degasser of claim 1, wherein the gassed tube and the degassed tube are colinear.

3. The inline liquid-degasser of claim 1, including a degassed chamber surrounding an exterior of the degassed tube and adjacent to the degassing chamber, the openings of the degassed tube communicating with the degassing chamber.

4. The inline liquid-degasser of claim 3, wherein the baffle separates the degassing chamber and the degassed chamber.

5. The inline liquid-degasser of claim 4, wherein:
the baffle has a solid portion without openings therethrough and a perforated portion with openings therethrough;
the gassed tube is sealed to one side of the solid portion and the degassed tube is sealed to another side of the solid portion; and
the perforated portion separates the degassing chamber and the degassed chamber.

6. The inline liquid-degasser of claim 3, wherein:
the gassed tube and the degassed tube are portions of a single tube; and
the baffle is sealed to a wall of the single tube.

7. The inline liquid-degasser of claim 6, including a perforated portion formed as a separate component than the baffle and disposed between the degassing chamber and the degassed chamber.

8. The inline liquid-degasser of claim 1, wherein the hollow fibers are arranged in rows of one or more hollow fibers.

9. The inline liquid-degasser of claim 8, wherein:
each of the rows contains a plurality of hollow fibers; and
the loop portions of the plurality of hollow fibers have respective radii.

10. The inline liquid-degasser of claim 9, wherein the plurality of hollow fibers are interconnected.

11. The inline liquid-degasser of claim 9, wherein the open ends of the hollow fibers of a row are at respective distances from each other.

12. The inline liquid-degasser of claim 1, wherein the degassing chamber has a square cross-section.

13. The inline liquid-degasser of claim 1, wherein the inline liquid-degasser has a rectangular shape.

14. The inline liquid-degasser of claim 1, containing a quick disconnect fitting coupled with an inlet port of the gassed tube.

15. The inline liquid-degasser of claim 1, containing a hose barb coupled with an outlet port of the degassed tube.

16. A degassing hose comprising:
an inline liquid-degasser including:
a gassed tube with openings formed through a wall of the gassed tube;
a degassed tube with openings formed through a wall of the degassed tube;
a baffle between the gassed tube and the degassed tube, the baffle configured to seal an interior of the gassed tube from an interior of the degassed tube;
a degassing chamber surrounding an exterior of the gassed tube, the openings of the gassed tube communicating with the degassing chamber;
a vacuum chamber disposed adjacent to the degassing chamber;
a vacuum port disposed through a wall of the vacuum chamber; and
a plurality of hollow fibers with open ends, the hollow fibers formed into loop portions and crown portions, the loop portions configured to surround the gassed tube in the degassing chamber, the crown portions configured to extend through a wall separating the degassing chamber and the vacuum chamber such that the open ends communicate with the vacuum chamber;
a quick disconnect fitting attached to the vacuum port;
a quick disconnect fitting attached to an end of the gassed tube;
a hose attached to an end of the degassed tube; and
a quick disconnect fitting attached to an end of the hose.

17. The degassing hose of claim 16, wherein the gassed tube and the degassed tube are colinear.

18. The degassing hose of claim 16, including a degassed chamber surrounding an exterior of the degassed tube and adjacent to the degassing chamber, the openings of the degassed tube communicating with the degassing chamber.

19. The degassing hose of claim 16, wherein:
the baffle has a solid portion without openings therethrough and a perforated portion with openings therethrough;
the gassed tube is sealed to one side of the solid portion and the degassed tube is sealed to another side of the solid portion; and
the perforated portion separates the degassing chamber and the degassed chamber.

20. A degassing heat-exchanger system comprising:
a heat exchanger including two liquid ports;
a first degassing hose coupled with one of the two liquid ports of the heat exchanger, the first degassing hose comprising:
an inline liquid-degasser including:
a gassed tube with openings formed through a wall of the gassed tube, an end of the gassed tube coupled with the one of the two liquid ports;
a degassed tube with openings formed through a wall of the degassed tube;
a baffle between the gassed tube and the degassed tube, the baffle configured to seal an interior of the gassed tube from an interior of the degassed tube;
a degassing chamber surrounding an exterior of the gassed tube, the openings of the gassed tube communicating with the degassing chamber;
a vacuum chamber disposed adjacent to the degassing chamber;
a vacuum port disposed through a wall of the vacuum chamber; and
a plurality of hollow fibers with open ends, the hollow fibers formed into loop portions and crown portions, the loop portions configured to surround the gassed tube in the degassing chamber, the crown portions configured to extend through a wall separating the degassing chamber and the vacuum chamber such that the open ends communicate with the vacuum chamber;
a hose coupled with an end of the degassed tube; and
a quick disconnect fitting attached to an end of the hose and configured to mate with a quick disconnect fitting on a server rack; and
a second degassing hose attached to another of the two liquid ports, the second degassing hose comprising:
an inline liquid-degasser including:
a gassed tube with openings formed through a wall of the gassed tube;
a degassed tube with openings formed through a wall of the degassed tube;
a baffle between the gassed tube and the degassed tube, the baffle configured to seal an interior of the gassed tube from an interior of the degassed tube;
a degassing chamber surrounding an exterior of the gassed tube, the openings of the gassed tube communicating with the degassing chamber;
a vacuum chamber disposed adjacent to the degassing chamber;
a vacuum port disposed through a wall of the vacuum chamber; and
a plurality of hollow fibers with open ends, the hollow fibers formed into loop portions and crown portions, the loop portions configured to surround the gassed tube in the degassing chamber, the crown portions configured to extend through a wall separating the degassing chamber and the vacuum chamber such that the open ends communicate with the vacuum chamber;
a quick disconnect fitting coupled with an end of the gassed tube and configured to mate with another quick disconnect fitting on the server rack; and
a hose coupling an end of the degassed tube with another of the two liquid ports of the heat exchanger; and
a vacuum line coupled to the vacuum port of the first degassing hose and the vacuum port of the second degassing hose.
